(19) United States
(12) Patent Application Publication
(10) Pub. No.: US 2014/0167170 A1
(43) Pub. Date: Jun. 19, 2014

(54) ELECTROSTATIC DISCHARGE PROTECTION DEVICE AND SEMICONDUCTOR STRUCTURE THEREOF

(71) Applicant: CHUNGHWA PICTURE TUBES, LTD., Taoyuan (TW)

(72) Inventors: Chih-Yu KUO, New Taipei City (TW); Wei-Lung LI, Taoyuan County (TW)

(73) Assignee: CHUNGHWA PICTURE TUBES, LTD., TAOYUAN (TW)

(21) Appl. No.: 13/845,062

(22) Filed: Mar. 17, 2013

(30) Foreign Application Priority Data
Dec. 17, 2012 (TW) 101224411

(51) Int. Cl. H01L 23/60

(52) U.S. Cl. CPC H01L 23/60
USPC 257/355

(57) ABSTRACT

An electrostatic discharge protection device for a liquid crystal display panel and a semiconductor structure thereof are disclosed. The semiconductor structure includes a gate electrode layer, a gate insulation layer, a semiconductor electrode layer, and a source/drain electrode layer. The gate electrode layer is disposed on a substrate and includes a taper. The gate insulation layer is disposed on the gate electrode layer and includes a first corner and a second corner. The semiconductor electrode layer is disposed on the gate insulation layer. The source/drain electrode layer is disposed on the semiconductor electrode layer. A first electrostatic discharge path and a second electrostatic discharge path are formed between the taper and the first and second corners.

### RELATED APPLICATIONS

This application claims priority to Taiwan Application Serial Number 101224411, filed Dec. 17, 2012, which is herein incorporated by reference.

### BACKGROUND

1. Field of invention

The present invention relates to an electrostatic discharge protection device and a semiconductor structure thereof, and, more particularly, to an electrostatic discharge protection device of a liquid crystal display (LCD) panel and a semiconductor structure thereof.

2. Description of Related Art

With the increasing importance of consumer electronics, new applications are continuously being developed. Moreover, users demand a higher and higher quality for the images displayed on electronic products. Therefore, high image resolution, a narrow bezel, and low power consumption have gradually become requisite characteristics of mainstream electronic products.

To satisfy the consumer requirement related to a narrow bezel structure, the industry has developed a gate-in-panel (GIP) technology. That is, through use of GIP technology, the panel of an electronic device is able to realize a narrow bezel structure.

Products must be tested at a panel manufacturing factory before shipping the same so as to ensure that customers do not purchase defective products. Therefore, after the manufacturing process, a panel is subjected to a panel light-on check which involves the examination of the appearance of the panel, as well as light-on inspection. Light-on inspection is directed to the inspection of point and line defects. Specifically, during a panel light-on check, a probe transmits a signal into the panel to make sure that data lines or scan lines are normal during operation for transmitting signals.

However, for panels of electronic products using GIP, more input signals are required because of the design requirements associated with such panels. Hence, during a panel light-on check, the electronic devices often encounter the problem of electrostatic discharge (ESD).

There has been much effort to try to find a solution to such an aforementioned problem. Nonetheless, there remains a need to improve existing apparatuses and techniques in the art.

### SUMMARY

The present invention provides an electrostatic discharge protection device for LCD panels to overcome the problems associated with panels of electronic products using GIP.

One aspect of the present invention is directed to an electrostatic discharge protection device of an LCD panel. The electrostatic discharge protection device comprises a semiconductor structure electrically connected to a trace under test. The semiconductor structure comprises a gate electrode layer, a gate insulation layer, a semiconductor electrode layer and a source/drain electrode layer. The gate electrode layer is disposed on a substrate, and has a cross section that is tapered along a direction away from the substrate to form a first taper end. The gate insulation layer comprises a first portion and a second portion. The first portion is conformally disposed along the outer surface of the gate electrode layer, whereas the second portion is disposed on the substrate. The first portion has a cross section that comprises a first corner and a second corner. The semiconductor electrode layer is disposed conformally along the outer surface of the gate insulation layer. The source/drain electrode layer is disposed conformally along the outer surface of the semiconductor electrode layer. A first electrostatic discharge path and a second electrostatic discharge path are formed by the first taper end together with the first corner and the second corner, respectively.

According to one embodiment of the present invention, the gate insulation layer comprises a first slit and a second slit respectively at the first corner and the second corner, such that the first electrostatic discharge path and the second electrostatic discharge path are respectively formed by the first taper end together with the first slit and the second slit.

According to another embodiment of the present invention, the gate electrode layer has a cross section having a shape of a triangle or a trapezoid.

According to yet another embodiment of the present invention, the first taper end of the gate electrode layer comprises at least two side surfaces converging at a line or a plane.

According to still another embodiment of the present invention, the direction away from the substrate is a vertical direction, and the gate electrode layer comprises first end and a second end disposed on opposite sides of the gate electrode layer along a horizontal direction. The first end has a cross section tapered toward the center of the gate electrode layer to form a second taper end in the horizontal direction.

According to yet another embodiment of present invention, the first end has a cross section having a shape of a triangle or a trapezoid.

According to still another embodiment of the present invention, the second taper end of the gate electrode layer comprises at least two side surfaces converging at a line or a plane.

According to yet another embodiment of the present invention, the source/drain electrode layer is disposed on the second taper end of the gate electrode layer.

According to one embodiment of the present invention, the electrostatic discharge protection device further comprises at least one electrostatic protection element. The electrostatic protection element is electrically connected to semiconductor structure.

According to still another embodiment of the present invention, the electrostatic discharge protection device is electrically connected to a GIP and a simple lighting circuit.

According to another embodiment of the present invention, static electricity generated by the trace under test is discharged via the first electrostatic discharge path and the second electrostatic discharge path when the trace under test is subjected to a simple lighting test.

According to yet another embodiment of the present invention, the semiconductor structure is disposed on the at least one electrostatic protection element.

According to still another embodiment of the present invention, the gate electrode layer is disposed on the at least one electrostatic protection element.

In view of the foregoing, the embodiments of the present invention provide an electrostatic discharge protection device and a semiconductor structure thereof, so as to improve the ESD problem encountered during a panel light-on check of an electronic product using GIP technology.

### BRIEF DESCRIPTION OF THE DRAWINGS

The invention can be more fully understood by reading the following detailed description of the embodiments, with reference made to the accompanying drawings as follows:

FIG. 1 schematically shows a panel of an electronic product using GIP technology.

FIG. 2 schematically shows a flow diagram for manufacturing an electrostatic discharge protection device according to one embodiment of the present invention.

FIG. 3A schematically shows a cross section of an electrostatic discharge protection device according to another embodiment of the present invention.

FIG. 3B schematically shows a cross section of an electrostatic discharge protection device according to yet another embodiment of the present invention.

FIG. 4 schematically shows an electrostatic discharge protection device according to still another embodiment of the present invention.

FIG. 5 schematically shows the arrangement of an electrostatic discharge protection device according to yet another embodiment of the present invention.

FIG. 6 schematically shows the arrangement of an electrostatic discharge protection device according to still another embodiment of the present invention.

FIG. 7 schematically shows the arrangement of an electrostatic discharge protection device and other electrostatic discharge protection structure(s) according to yet another embodiment of the present invention.

FIG. 8 schematically shows the arrangement of an electrostatic discharge protection device and other electrostatic discharge protection structure(s) according to still another embodiment of the present invention.

### DETAILED DESCRIPTION

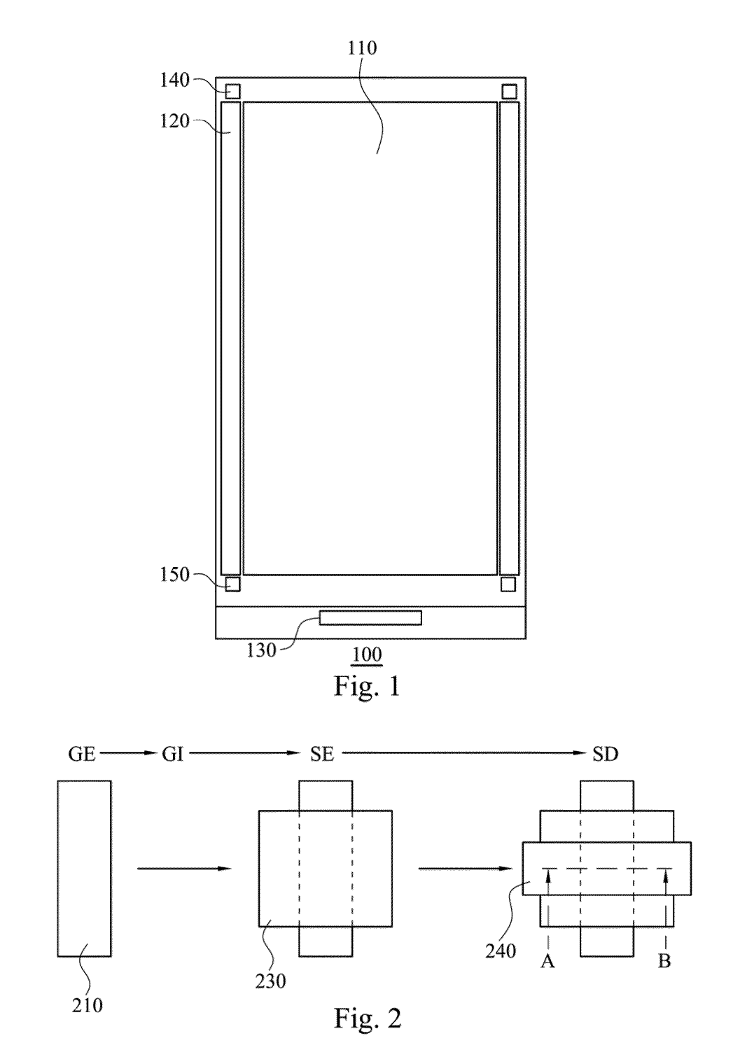

FIG. 1 depicts a panel structure 100 of an electronic product using GIP technology. The panel structure 100 comprises panel 110, a GIP 120, a simple lighting circuit 130, a first position 140 and a second position 150. Since more input signals are required because of the design requirements associated with the panel structure 100 utilizing GIP technology, the panel structure 100 is more vulnerable to the problem of ESD during a panel light-on check. To address the above-mentioned problem, embodiments of the present invention provide an electrostatic discharge protection device of an LCD panel which may be selectively disposed at a first position 140 or a second position 150 (depending on actual needs) to release static charges, thereby protecting the panel 100 of the electronic product using GIP technology from being destroyed by static electricity. The semiconductor structure is described in detailed hereinafter.

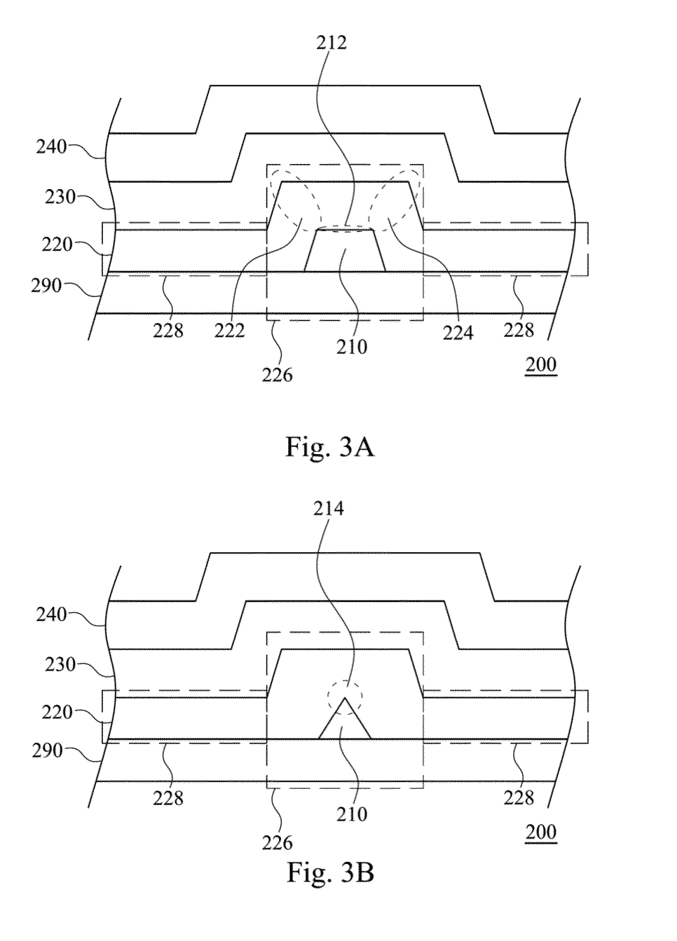

FIG. 2 is a flow diagram illustrating the process for manufacturing the electrostatic discharge protection device of an LCD panel according to one embodiment of the present invention. It takes four processes to manufacture the semiconductor structure of the electrostatic discharge protection device. First, a gate electrode (GE) layer 210 is formed on a substrate (not shown). Next, a gate insulation (GI) layer, which will be described with reference to FIG. 3, is formed on the gate electrode layer 210, and a semiconductor electrode (SE) layer 230 is formed on the gate insulation layer. Subsequently, a source/drain (SD) electrode layer 240 is formed on the semiconductor electrode layer 230. In FIG. 2, since the gate insulation layer of the electrostatic discharge protection device may be silicon nitride, it completely covers the gate electrode layer 210, and hence, no mask is used.

To facilitate understanding of the present invention, the electrostatic discharge protection device of FIG. 2 is sectioned along line A-B, and the resulting cross-sectional views thereof are illustrated in FIGS. 3A and 3B.

As illustrated in FIG. 3A, the electrostatic discharge protection device 200 of the LCD panel comprises the gate electrode layer 210, the gate insulation layer 220, the semiconductor electrode layer 230 and the source/drain electrode layer 240. The gate electrode layer 210 may be disposed on the substrate 290. As illustrated in the figure, the cross section of the gate electrode layer 210 is tapered along a direction away from the substrate 290, thereby forming a first taper end 212 opposite to the substrate 290 (i.e., farthest from the substrate 290). The gate insulation layer 220 comprises a first portion 226 and a second portion 228. The first portion 226 is disposed conformally along the outer surface of the gate electrode layer 210, whereas the second portion 228 is disposed on the substrate 290. The cross section of the first portion 226 comprises a first corner 222 and a second corner 224.

Further, the semiconductor electrode layer 230 is disposed onformally along the outer surface of the gate insulation layer 220. The source/drain electrode layer 240 is disposed conformally along the outer surface of the semiconductor electrode layer 230. As illustrated in the figure, a first electrostatic discharge path and a second electrostatic discharge path may be formed by the first taper end 212 together with the first corner 222 and the second corner 224, respectively. In one embodiment, the first and second electrostatic discharge paths may be extended to the corners of the semiconductor electrode layer 230 and the source/drain electrode layer 240. However, the present invention is not limited to the structure depicted in FIG. 3A, which only serves as an example of one embodiment of the present invention. Any alteration or modification to the structure illustrated in FIG. 3A without departing from the spirits of the present invention falls within the scope of the present invention.

As described above, the gate electrode layer 210 comprises the first taper end 212. As a result, static charges may be induced by the first taper end 212 easily, and moreover, the static charges may be discharged through the first and second electrostatic discharge paths formed by the first taper end 212 together with the first and second corners 222, 224, respectively. Therefore, the problem of ESD associated with electronic products using GIP technology during a panel light-on check may be ameliorated.

In one embodiment, the gate insulation layer 220 comprises a first slit and a second slit at the first corner 222 and second corner 224, respectively. In this way, the first electrostatic discharge path and second electrostatic discharge path are respectively formed by the first taper end 212 together with the first slit and second slit. Specifically, the slits are formed when excessive film-formation of the gate insulation layer 220 occurs at the corner. A channel is formed along the slits, thereby inducing the generation of static charges when the gate electrode layer 210 and the semiconductor electrode layer 230 have different voltage levels. Therefore, the first electrostatic discharge path and the second electrostatic discharge path are formed between the first taper end 212 and the first slit and second slit, respectively. In view of the foregoing, embodiments of the present invention overcome what some persons having ordinary skill in the art believe to be problems associated with including a slit(s) in a semiconductor structure, namely, a slit(s) would jeopardize the performance of the semiconductor structure. Moreover, the first and second slits are further used for electrostatic protection.

In another embodiment, as illustrated in FIG. 3A, the first taper end 212 of the gate electrode layer 210 has at least two side surfaces converging at a same plane. In other words, the first taper end 212 of the gate electrode layer 210 has a cross-sectional shape of a trapezoid.

Another embodiment of the present invention is illustrated in FIG. 3B. The electrostatic discharge protection device 200 of FIG. 3B is different from that of FIG. 3A in that a first taper end 214 of the gate electrode layer 210 has at least two side surfaces that converge at a same line. In other words, the first taper end 214 of the gate electrode layer 210 has a cross-sectional shape of a triangle, such that the first taper end 214 of the gate electrode layer 210 is forms a point-discharging structure that achieves a point-end discharging effect. Such a point-end discharging effect facilitates the release of static charges.

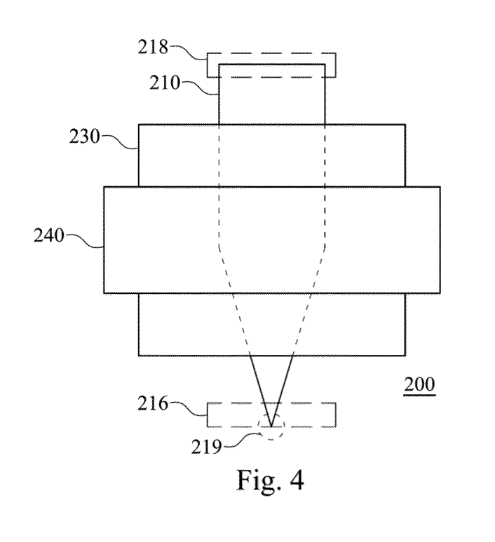

The present invention further provides the structure depicted in FIG. 4. With this structure, the electrostatic discharge protection device of embodiments of the present invention achieves a better electrostatic protection effect.

For convenience in describing the structure depicted in FIG. 4, the direction away from the substrate may be referred to as a vertical direction. That is, the vertical direction is substantially normal to the substrate and may point away from the substrate, or alternatively may point in the direction that the reader is viewing FIG. 4 (i.e., toward the substrate). The gate electrode layer 210 comprises a first end 216 and a second end 218 disposed on opposite sides of the gate electrode layer 210 along a horizontal direction. The first end 216 has a cross section that is tapered toward the center of the gate electrode layer 210, thereby forming a second taper end 219 in the horizontal direction. In this way, in addition to the first and second electrostatic discharge paths formed by the first taper end 212 together with the first and second corners 222, 224, the electrostatic discharge protection device 200 is able to perform discharging of static charges also via the second taper end 219.

In one embodiment, as illustrated in FIG. 4, the second taper end 219 of the gate electrode layer 210 has at least two side surfaces converging at a same line. In other words, the second taper end 219 of the gate electrode layer 210 has a cross-sectional shape of a triangle, such that the second taper end 219 of the gate electrode layer 210 forms a point-discharging structure that achieves a point-end discharging effect. Such a point-end discharging effect facilitates the release of static charges. However, the present invention is not limited to the above-mentioned structure. In other embodiments, the second taper end 219 of the gate electrode layer 210 has at least two side surfaces converging at a same plane. In other words, the second taper end 219 of the gate electrode layer 210 has a cross-sectional shape of a trapezoid. In one embodiment, the source/drain electrode layer 240 is disposed on the second taper end 219 of the gate electrode layer 210. This arrangement induces the release of static charges between the source/drain electrode layer 240 and the second taper end 219.

As illustrated in FIG. 1, the electrostatic discharge protection device provided by the present invention embodiment, depending on actual needs, may be selectively disposed at the first position 140 or the second position 150, and electrically connected to the gate-in-panel 120 and the simple lighting circuit 130. The actual arrangement of the electrostatic discharge protection device is described in detail hereinafter.

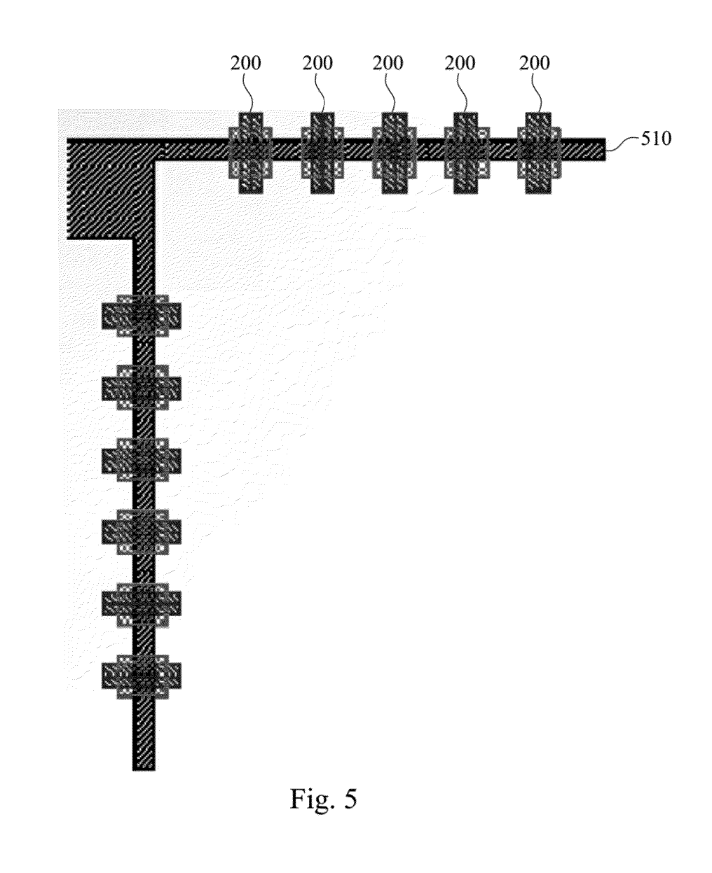

FIG. 5 schematically illustrates the electrostatic discharge protection device according to one embodiment of the present invention. As illustrated in FIG. 5, element label 510 is a trace under test of the panel, and the electrostatic discharge protection device 200 may be manufactured as a unit-structure. A plurality of the electrostatic discharge protection devices 200 may be disposed on the trace under test 510 of the panel in a spaced-apart manner, so as to release static charges generated during a panel light-on check, thereby preventing the trace under test 510 of the panel from being damaged by the static charges.

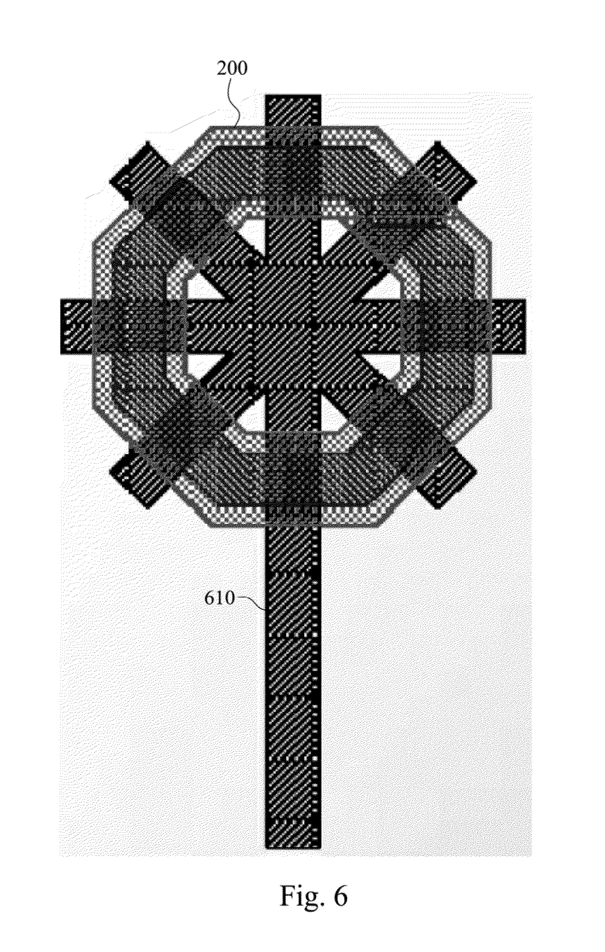

FIG. 6 schematically depicts another arrangement of the electrostatic discharge protection device 200. Element label 610 is a trace under test of the panel, and the electrostatic discharge protection device 200 may be manufactured as a ring structure which is disposed on the trace under test 610 of the panel, so as to release static charges generated during a panel light-on check, thereby preventing the trace under test 610 of the panel from being damaged by the static charges.

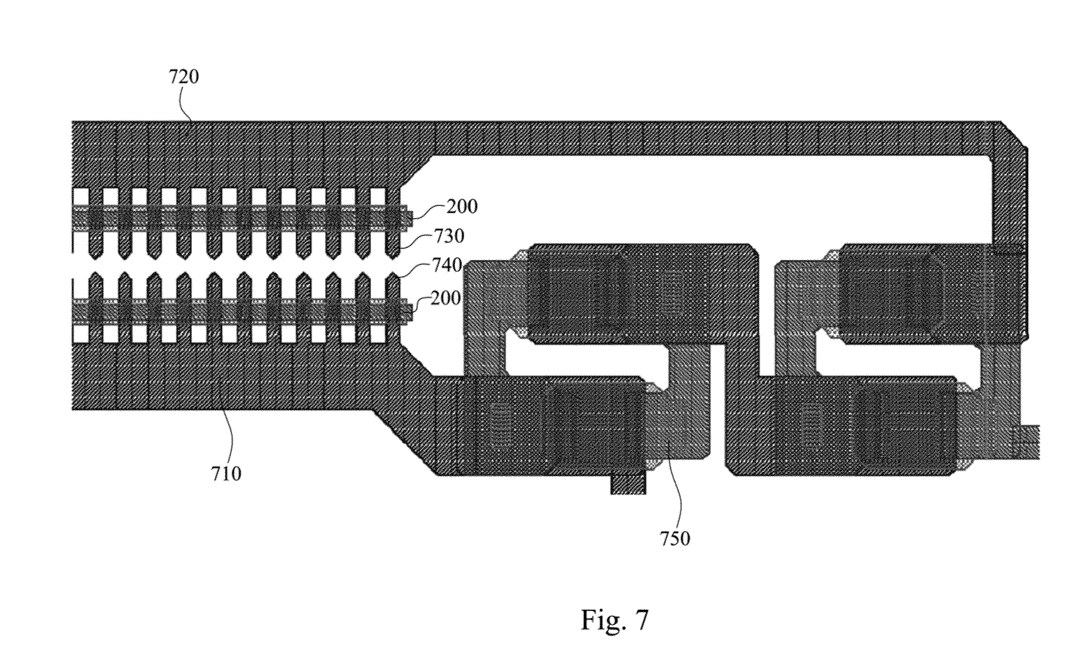

To provide a better electrostatic protection effect for the panel structure 100 of the electronic product using GIP technology, an electrostatic discharge protection device may be used together th other electrostatic protection element(s). FIG. 7 illustrates the arrangement of the electrostatic discharge protection device 200 together with other electrostatic protection elements according to embodiments of the present invention. As illustrated in the figure, element label 710 is a trace under test of the panel, and element label 720 is a signal line. There is a voltage difference between the trace under test 710 and the signal line 720, and static electricity generated by a panel light-on check may be released via the point discharging structures 730, 740. In this case, the electrostatic discharge protection device 200 is disposed on the point discharging structures 730, 740, such that, static electricity generated by the trace under test 710 is discharged by the first and second electrostatic discharge paths of the electrostatic discharge protection device 200 when the trace under test 710 is subjected to a light-on test. In one embodiment, the gate electrode layer 210 of the electrostatic discharge protection device 200 is disposed on the point discharging structures 730, 740. Further, the electrostatic discharge protection device 200 may be used together with a diode-type electrostatic protection structure 750.

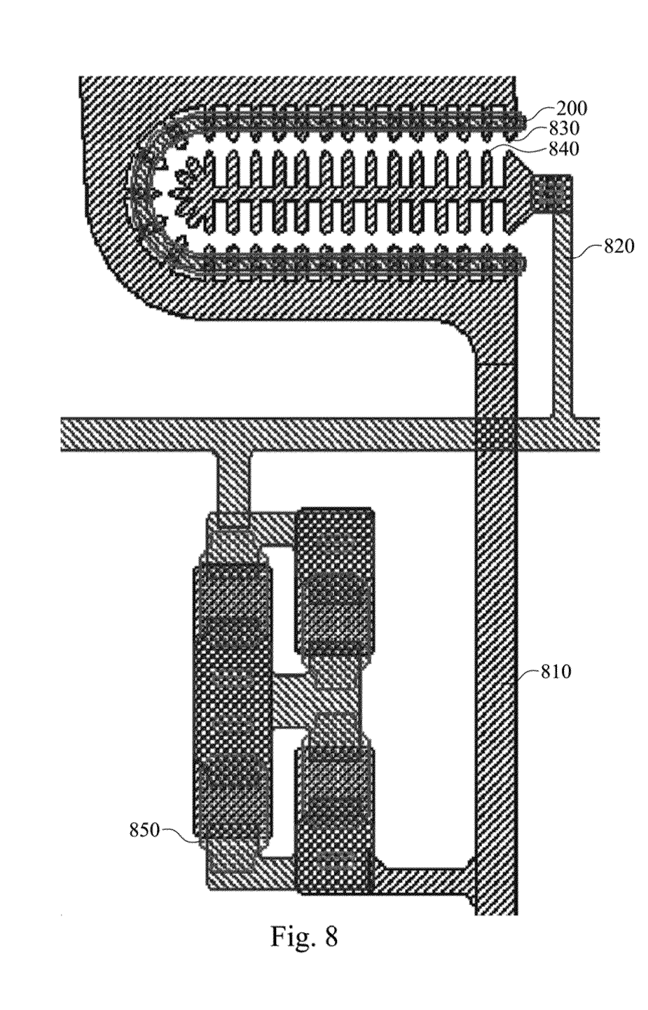

FIG. 8 illustrates another arrangement of the electrostatic discharge protection device 200 together with other electrostatic protection elements. As illustrated in the figure, element label 810 is a trace under test of the panel, and element label 820 is a signal line. There is a voltage difference between the trace under test 810 and the signal line 820, and static electricity generated by a panel light-on check may be released via the point discharging structures 830, 840. In this case, the electrostatic discharge protection device 200 is disposed on the point discharging structures 830, 840, such that static electricity generated by the trace under test 810 is discharged by the first and second electrostatic discharge paths of the electrostatic discharge protection device 200 when the trace under test 810 is subjected to simple light-on test. In one embodiment, the gate electrode layer 210 of the electrostatic discharge protection device 200 is disposed on the point discharging structures 830, 840. Further, the electrostatic discharge protection device 200 may be used together with a diode-type electrostatic protection structure 850. However, the present invention is not limited to the structures disclosed in FIGS. 5, 6, 7, and 8, and persons having ordinary skill in the art may arrange the electrostatic discharge protection device 200, the point discharging structures 730, 740, 830, 840 and diode-type electrostatic protection structures 750, 850, depending on actual needs.

In view of the foregoing embodiments of the present invention, the application of the present invention has the advantages as follows. Embodiments of the present invention disclose an electrostatic discharge protection device of an LCD panel and a semiconductor structure thereof, in which the electrostatic discharge protection device is used to overcome the ESD problem often associated with electronic products using GIP technology and which is encountered during a panel light-on check.

What is claimed is:

1. An electrostatic discharge protection device, comprising a semiconductor structure electrically connected to a trace under test, wherein the semiconductor structure comprises:
a gate electrode layer disposed on a substrate, wherein the gate electrode layer has a cross section tapered along a direction away from the substrate to form a first taper end;
a gate insulation layer comprising a first portion and a second portion, wherein the first portion is conformally disposed along the outer surface of the gate electrode layer, wherein the cross section of the first portion comprises first corner and a second corner, and the second portion is disposed on the substrate;
a semiconductor electrode layer disposed conformally along the outer surface of the gate insulation layer; and
a source/drain electrode layer disposed conformally along the outer surface of the semiconductor electrode layer;
wherein a first electrostatic discharge path and a second electrostatic discharge path are respectively formed by the first taper end with the first corner and the second corner.

2. The electrostatic discharge protection device according to claim 1, wherein the gate insulation layer comprises a first slit and a second slit respectively disposed at the first corner and the second corner, wherein the first electrostatic discharge path and the second electrostatic discharge path are respectively formed by the first taper end with the first slit and the second slit.

3. The electrostatic discharge protection device according to claim 1, wherein the cross section of the gate electrode layer has a shape of a triangle or a trapezoid.

4. The electrostatic discharge protection device according to claim 1, wherein the first taper end of the gate electrode layer comprises at least two side surfaces converging at a line or a plane.

5. The electrostatic discharge protection device according to claim 1, wherein the direction away from the substrate is a vertical direction, and the gate electrode layer comprises a first end and a second end disposed on opposite sides of the gate electrode layer along a horizontal direction, wherein the first end has a cross section tapered toward the center of the gate electrode layer to form a second taper end in the horizontal direction.

6. The electrostatic discharge protection device according to claim 5, wherein the cross section of the first end has a shape of a triangle or a trapezoid.

7. The electrostatic discharge protection device according to claim 6, wherein the second taper end of the gate electrode layer comprises at least two side surfaces converging at a line or a plane.

8. The electrostatic discharge protection device according to claim 5, wherein the source/drain electrode layer is disposed on the second taper end of the gate electrode layer.

9. The electrostatic discharge protection device according to claim 1, further comprising:
at least one electrostatic protection element electrically connected to the semiconductor structure.

10. The electrostatic discharge protection device according to claim 1, wherein the electrostatic discharge protection device is electrically connected to a gate-in-panel and a simple lighting circuit.

11. The electrostatic discharge protection device according to claim 1, static electricity generated by the trace under test is discharged via the first electrostatic discharge path and the second electrostatic discharge path when the trace under test is subjected to a simple lighting test.

12. The electrostatic discharge protection device according to claim 9, wherein the semiconductor structure is disposed on the at least one electrostatic protection element.

13. The electrostatic discharge protection device according to claim 12, wherein the gate electrode layer is disposed on the at least one electrostatic protection element.
